(19) United States
(12) Patent Application Publication
(10) Pub. No.: US 2026/0171353 A1
(43) Pub. Date: Jun. 18, 2026

(54) CHARGED PARTICLE BEAM DEVICE AND METHOD FOR CONTROLLING CHARGED PARTICLE BEAM DEVICE

(71) Applicant: HITACHI HIGH-TECH SCIENCE CORPORATION, Tokyo (JP)

(72) Inventors: Shota TORIKAWA, Tokyo (JP); Yo YAMAMOTO, Tokyo (JP)

(21) Appl. No.: 18/710,554

(22) PCT Filed: Nov. 15, 2021
(86) PCT No.: PCT/JP2021/041907

§ 371 Date: May 15, 2024

(51) Int. Cl. H01J 37/302; H01J 37/20

(52) U.S. Cl. CPC H01J 37/3023; H01J 37/20; H01J 2237/20285

(57) ABSTRACT

This charged particle beam device, which is for processing a sample, comprises: a charged particle beam-emitting optical system that emits a charged particle beam; a sample stage that holds a sample; a drive mechanism that drives the sample stage; and a computer that sets a cross-section of the sample in a processing region of the sample and controls the charged particle beam-emitting optical system and the drive mechanism when slicing the set processing region. The computer sets an irradiation location in a position where each of a plurality of emitted charged particle beams overlap one another in a first direction of the sample processing region when slicing the processing region.

### CROSS REFERENCE

The present application for patent is a 371 national phase filing of International Patent Application No. PCT/JP2021/041907 by TORIKAWA et al., entitled “CHARGED PARTICLE BEAM DEVICE AND METHOD FOR CONTROLLING CHARGED PARTICLE BEAM DEVICE” filed Nov. 15, 2021, assigned to the assignee hereof, and expressly incorporated by reference herein.

### TECHNICAL FIELD

The present invention relates to a charged particle beam device and a method for controlling a charged particle beam device.

### BACKGROUND ART

Processing performed at regular intervals in a depth direction of a cross section of a sample that is previously prepared using a charged-particle beam system is called slice processing. Slice processing is performed primarily by irradiating a cross section of a sample with a charged particle beam, and the amount of the emitted charged particle beam for the processing at each spacing is always constant.

With regard to slicing processing, there is known technology that can achieve a highly precise machining pitch over a wide area (see, for example, Patent Document 1). This technology synchronizes two or more types of FIB deflection control: high-definition scanning with a precise deflection amount and image shifting with a large deflection amount, to scan a larger area at a higher density than before. Furthermore, the SEM image shift is made to follow the location processed using the FIB image shift. Multiple SEM images are acquired for a single cross section that is prepared, and then spliced to create a high-resolution image.

There are two known methods: one is to set the slice processing interval numerically, and the other is to set the diameter size of the charged particle beam used for the slicing process. When the processing interval is set numerically, slicing is performed at the set interval. When the diameter size of the charged particle beam is set, the processing interval is determined depending on the set diameter size, and slicing is performed at the determined processing interval.

It is also known that emission of a charged particle beam to a cross section of a sample improves the sputtering efficiency compared to emission of a charged particle beam to the surface of a sample surface due to the edge effect. By emitting a charged particle beam to an appropriate location of the cross section of the sample and maximizing the edge effect, the processing time can be greatly reduced. The irradiation location of the charged particle beam that maximizes the edge effect depends on the current density distribution and beam diameter of the beam used for slice processing as well as the emission angle of the beam.

The sputtering efficiency is maximized when the beam emission angle with respect to the sample surface is about 80°. When the beam emission angle is 30° or more and 89.8° or less, a sufficient increase in sputtering efficiency can be expected.

When the beam emission angle with respect to the sample surface is 90°, the relationship between the processing depth and the resulting cross-sectional angle θ depending on the current density distribution is expressed as 0=Arctan (depth/beam radius).

### Document of Related Art

### Patent Document

Patent Document 1: Japanese Patent Application Publication No. 2013-089431

### DISCLOSURE

### Technical Problem

When a charged particle beam is not emitted to an appropriate location of a cross section of a sample, the edge effect cannot be obtained. When the edge effect is not obtained, a slicing depth gradually becomes shallower. To deepen the slicing depth, the emission dose of the charged particle beam is gradually increased. When the emission dose of the charged particle beam is increased, the time required for slicing increases.

The present invention has been made in view of the above-described points, and it is an object to provide a charged particle beam device that can shorten the time required for slicing and to provide a method for controlling the charged particle beam device.

### Technical Solution

In order to solve the above problem and achieve the object, the present invention employs aspects described below.

(1) A charged particle beam device according to one aspect of the present invention is a charged particle beam device for processing a sample, the device including: a charged particle beam-emitting optical system that emits a charged particle beam; a sample stage that holds a sample; a drive mechanism that drives the sample stage; and a computer that sets a cross section of the sample in a processing region of the sample and controls the charged particle beam-emitting optical system and the drive mechanism when the set processing region is sliced, in which the computer sets an irradiation location to a location where a plurality of charged particle beams emitted in a first direction of the processing region overlap one another when the processing region is sliced.

(2) In the charged particle beam device of (1) above, the computer sets a spacing between each of the plurality of charged particles beams emitted in the first direction to be more than or equal to 50% and less than or equal to 90% of diameter of the charged particle beam.

(3) In the charged particle beam device of (1) or (2) above, the computer sets the irradiation location at a location where each of one or a plurality of charged particle beams emitted in a second direction orthogonal to the first direction overlap when the processing region of the sample is sliced.

(4) In the charged particle beam device of (3) above, the computer sets a spacing between each of the plurality of charged particles beams emitted in the second direction to be more than or equal to 50% and less than or equal to 90% of the diameter of the charged particle beam.

(5) In the charged particle beam device of (1) above, the computer sets a processing depth for each of the plurality of charged particles beams emitted in the first direction be a desired processing depth multiplied by a number that is more than or equal to Tan 30° and less than or equal to Tan 89.8° of a beam radius

(6) A method for controlling a charged particle beam device according to one aspect of the present invention is a method for controlling a charged particle beam device including a charged particle beam-emitting optical system that emits a charged particle beam, a sample stage that holds a sample, a drive mechanism that drives the sample stage, and a computer that sets a cross section in a processing region of the sample and controls the charged particle beam-emitting optical system and the drive mechanism when the processing region that is set is sliced, the method including: a step in which the computer sets an irradiation location to a location where a plurality of charged particle beams emitted in a first direction of the processing region overlap one another when the processing region is sliced; and a step in which the computer controls the charged particle beam-emitting optical system and the drive mechanism so as to slice the sample by irradiating the irradiation location that is set with the charged particle beam.

### Advantageous Effects

According to the present invention, the time required for a slicing process can be reduced.

### DESCRIPTION OF RELATED ART

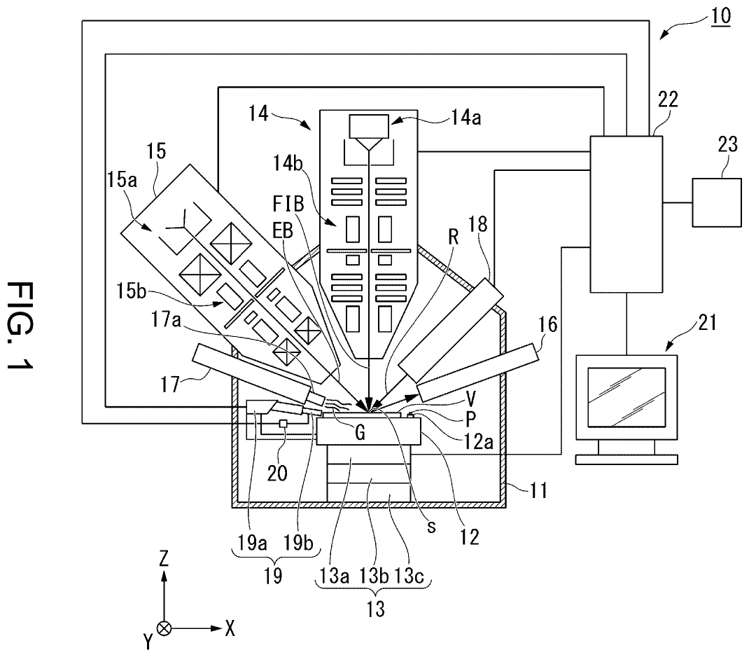

FIG. 1 is a schematic configurational diagram illustrating a charged particle beam device according to one embodiment of the present invention.

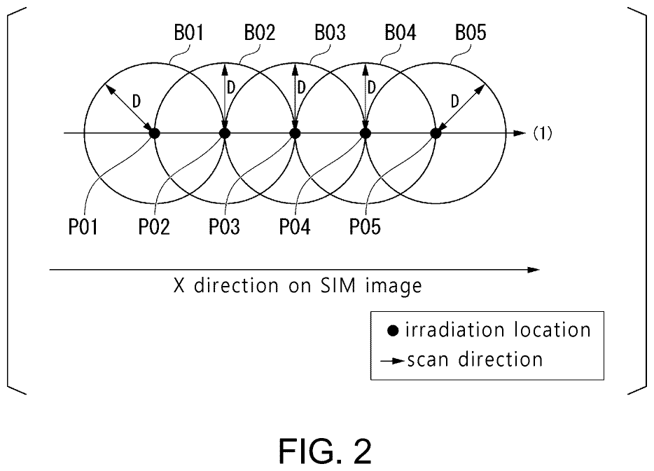

FIG. 2 is a diagram illustrating Example 1 of a location to be irradiated with a charged particle beam of the charged particle beam device according to the embodiment.

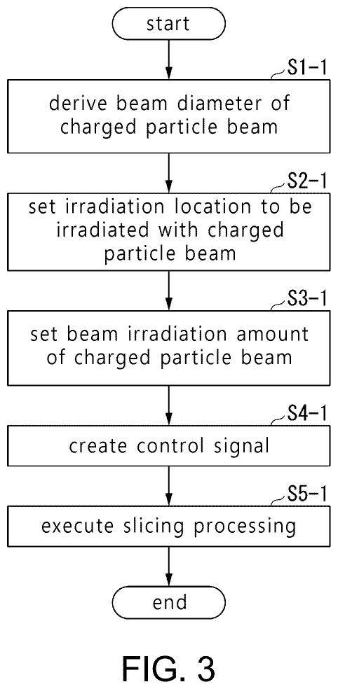

FIG. 3 is a flowchart illustrating Example 1 of processing procedures of the charged particle beam device according to the embodiment.

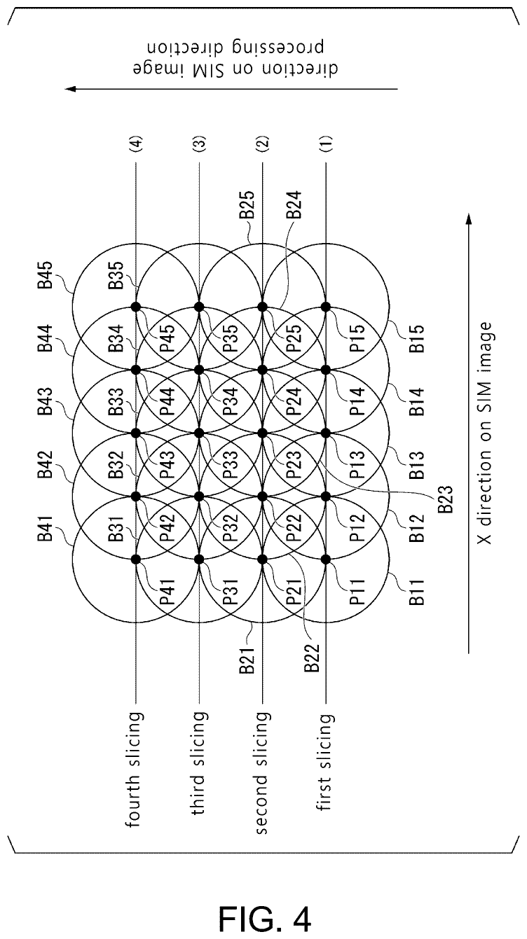

FIG. 4 is a diagram illustrating Example 2 of a location to be irradiated with a charged particle beam of the charged particle beam device according to the embodiment.

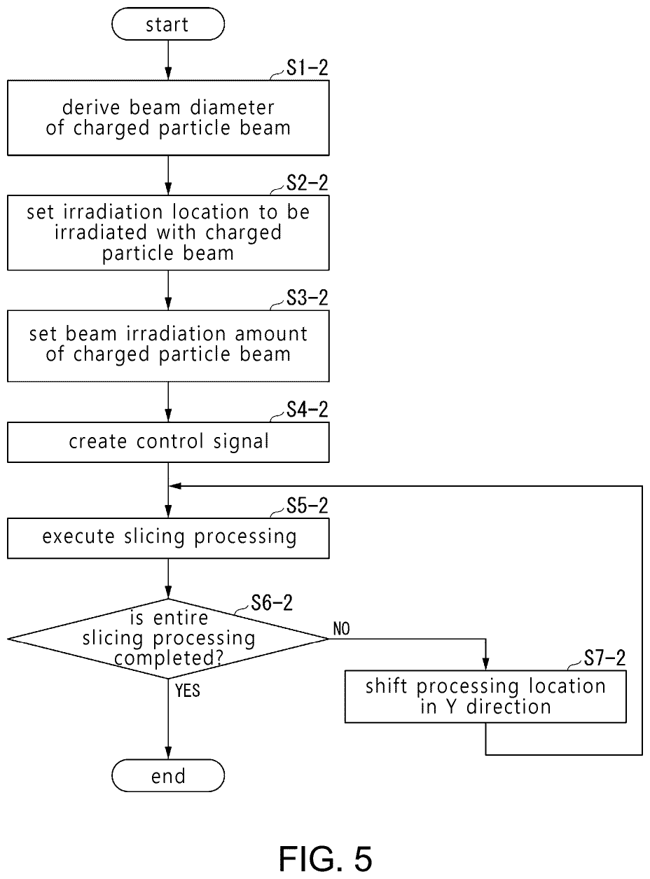

FIG. 5 is a flowchart illustrating Example 2 of processing procedures of the charged particle beam device according to the embodiment.

### BEST MODE

Next, a charged-particle beam device and a control method of the charged-particle beam device will be described with reference to the drawings. The embodiments described below are only for illustrative purposes, and embodiments of the present invention are not limited thereto.

Throughout the drawings used to describe the embodiments, parts having the same function are denoted by the same symbols, and a redundant description of such parts will be omitted.

FIG. 1 is a schematic configurational diagram illustrating a charged particle beam device according to one embodiment of the present invention.

The charged particle beam device 10 according to one embodiment of the present invention is used to slice a sample. The charged particle beam device 10 emits a charged particle beam. The charged particle beam device 10 includes: a charged particle beam-emitting optical system that emits a charged particle beam; a sample stage that holds a sample; a drive mechanism that drives the sample stage; and a computer that sets a cross-section of the sample in a processing region of the sample and controls the charged particle beam-emitting optical system and the drive mechanism when the set processing region is sliced. The computer sets an irradiation location to a location where each of a plurality of charged particle beams emitted in a first direction, such as X-axis direction, of the sample processing region overlap when the sample is sliced in the processing region. Specifically, as illustrated in FIG. 1, the charged particle beam device 10 includes a sample chamber 11 whose interior can be maintained in a vacuum state, a stage 12 that can fix a bulk sample V or a sample piece holder P that holds a sample piece S in the sample chamber 11, and a stage drive mechanism 13 that drives the stage 12.

The charged particle beam device 10 is equipped with a focused ion beam (FIB)-emitting optical system 14 that emits a charged particle beam, such as a focused ion beam (FIB), to an irradiation target within a predetermined irradiation region (i.e., scanning range) in the sample chamber 11. The charged particle beam device 10 is equipped with an electron beam-emitting optical system 15 that emits an electron beam (EB) to an irradiation target within a predetermined irradiation region in the sample chamber 11. The charged particle beam device 10 is equipped with a detector 16 that detects secondary charged particles (such as secondary electrons and secondary ions) generated from the irradiation target irradiated with a focused ion beam or an electron beam. The charged particle beam device 10 is equipped with a gaseous ion beam-emitting optical system 18 that emits a gaseous ion beam (GB) to an irradiation target in a predetermined irradiation region in the sample chamber 11.

The focused ion beam-emitting optical system 14, the electron beam-emitting optical system 15, and the gaseous ion beam-emitting optical system 18 are arranged so that the beam irradiation axes thereof intersect each other at a single point on the stage 12. That is, when the sample chamber 11 is viewed in plane from one side, the focused ion beam-emitting optical system 14 is positioned along the vertical direction, and the electron beam-emitting optical system 15 and the gaseous ion beam-emitting optical system 18 are positioned along an oblique direction, for example, inclined at angle of 45° with respect to the vertical direction. With such an arrangement layout, when the sample chamber 11 is viewed in plan from one side, the beam irradiation axis of the gas ion beam (GB) orthogonally intersects the beam irradiation axis of the electron beam (EB) irradiated from the electron beam-emitting optical system 15.

The charged particle beam device 10 is equipped with a gas supply unit 17 that supplies gas G to the surface of the sample S. An example of the gas supply unit 17 is specifically a nozzle 17a with an outer diameter of about 200 μm.

The charged particle beam device 10 includes a sample transfer means 19 and an absorption current detector 20. Here, the sample transfer means 19 includes a needle 19a that takes a sample piece S from a sample V fixed on the stage 12, holds the sample piece S, and transfers the sample piece S to the sample piece holder P, and the sample transfer means 19 further includes a needle drive mechanism 19b that drives the needle 19a to transfer the sample piece S. The absorption current detector 20 detects a charged particle beam inflow current (also referred to as absorption current) flowing to the needle 19a and sends an inflow current signal to the computer so that the inflow current signal can be imaged.

The charged particle beam device 10 is equipped with a display device 21 that displays image data and other data on the basis of the secondary charged particles R detected by the detector 16, a computer 22, and an input device 23.

The irradiation target of the focused ion beam-emitting optical system 14 and the irradiation target of the electron beam-emitting optical system 15 are the sample V fixed on the stage 12, the sample piece S, and the needle 19a or sample piece holder P disposed in the irradiation region.

The charged particle beam device 10 can perform imaging of the irradiated region, sputtering-assisted processing (such as drilling and trimming), etching processing, slicing processing, deposition film formation, etc. by scanning the surface of the irradiation target with a charged particle beam. The charged particle beam device 10 can perform a process of cutting a sample piece S from a sample V and processing the sample piece S to form a micro sample piece Q for observation with a transmission electron microscope (TEM) or an analytical sample piece using an electron beam. An example of the micro sample piece Q is a lamella sample, needle-shaped sample, etc.

The charged particle beam device 10 is capable of thinning the tip of a sample piece S transferred to the sample piece holder P until the tip of the sample has the desired thickness suitable for transmission electron microscopic observation (for example, thickness of 5 nm to 100 nm), thereby obtaining a micro sample piece Q for observation. The charged particle beam device 10 enables observation of the surface of the irradiation target by emitting a charged particle beam or an electron beam to the surface of the irradiation target, such as the sample piece S and the needle 19a, while scanning the surface of the irradiation target.

The absorption current detector 20 is equipped with a preamplifier that amplifies the current flowing into the needle and sends the amplified current to the computer 22. The needle inflow current detected by the absorption current detector 20 and the signal synchronized with the scanning of the charged particle beam enable the display device 21 to display a needle-shaped absorption current image so that the needle shape or the needle tip position can be identified.

The sample chamber 11 can be evacuated by an air exhauster (not illustrated) until the interior of the sample chamber 11 reaches the desired vacuum state and maintain the desired vacuum state.

The stage 12 holds the sample V. The stage 12 is equipped with a holder fixing stand 12a that holds the sample piece holder P thereon. This holder fixing stand 12a may be structured to support a plurality of sample piece holders P.

The stage drive mechanism 13 is disposed in the sample chamber 11 in a state of being connected to the stage 12, and displaces the stage 12 with respect to a predetermined axis according to a control signal output from the computer 22. The stage drive mechanism 13 is equipped with a moving mechanism 13a that moves the stage 12 along each of X and Y axes that are parallel to the horizontal plane and are orthogonal to each other, and along Z axis that is orthogonal to each of the X and Y axes. The stage drive mechanism 13 includes a tilt mechanism 13b that tilts the stage 12 around the X or Y axis and a rotation mechanism 13c that rotates the stage 12 around the Z axis.

The focused ion beam-emitting optical system 14 is fixed to the sample chamber 11, with the beam emitting portion (not illustrated) thereof facing down the stage 12 in the vertical direction within the irradiation region in the sample chamber 11, and with the optical axis thereof being parallel to the vertical direction. This arrangement makes it possible to perpendicularly apply a charged particle beam to the irradiation target such as the sample V mounted on the stage 12, the sample piece S, or the needle 19a disposed within the irradiation region directly from above the irradiation target object.

The charged particle beam device 10 may be equipped with other ion beam-emitting optical systems instead of the focused ion beam-emitting optical system 14 described above. The ion beam-emitting optical system is not limited to the optical system that forms a charged particle beam as described above. The ion beam-emitting optical system may be, for example, a projection-type ion beam-emitting optical system that provides a stencil mask with a shaped opening in the optical system and forms a shaped beam with the shape of the opening of the stencil mask. This projection-type ion beam-emitting optical system can form a shaped beam with a shape corresponding to the processing region around the sample piece S with high precision and can reduce the processing time.

The focused ion beam-emitting optical system 14 is equipped with an ion source 14a that generates ions and an ion optical system 14b that focuses and deflects the ion extracted from the ion source 14a. The ion source 14a and the ion optical system 14b are controlled according to control signals output from the computer 22, and the irradiation location and irradiation conditions of the charged particle beam are controlled by the computer 22.

The ion source 14a is, for example, a liquid metal ion source using liquid gallium or the like, a plasma ion source, or a gas field ion source. The ion optical system 14b is equipped with, for example, a first electrostatic lens, such as a condenser lens, an electrostatic deflector, and a second electrostatic lens, such as an objective lens. When a plasma-type ion source is used as the ion source 14a, high-speed processing can be achieved with a high-current beam which makes it suitable for the extraction of large-sized sample pieces S. For example, by using argon ions as a gas field ion source, an argon ion beam can be emitted from the focused ion beam-emitting optical system 14.

The electron beam-emitting optical system 15 is fixed to the sample chamber 11, with the beam emitting portion (not illustrated) thereof facing down the stage 12 in an oblique direction inclined by a predetermined angle (for example, 60°) with respect to the perpendicular direction of the stage 12 within the irradiation region inside the sample chamber 11, and with the optical axis thereof being parallel to the oblique direction. This arrangement makes it possible to apply an electron beam to the irradiation target such as the sample V fixed to the stage 12, the sample piece S, and the needle 19a disposed within the irradiation region, from above the irradiation target object in the oblique direction.

The electron beam-emitting optical system 15 is equipped with an electron source 15a that generates electrons and an electron optical system 15b that focuses and deflects the electrons emitted from the electron source 15a. The ion source 15a and the ion optical system 15b are controlled according to control signals output from the computer 22, and the irradiation location and irradiation conditions of the electron beam are controlled by the computer 22. The electron optical system 15b is equipped with, for example, an electromagnetic lens and a deflector.

The positions of the electron beam-emitting optical system 15 and focused ion beam-emitting optical system 14 may be switched, so that the electron beam-emitting optical system 15 may be positioned in the vertical direction and the focused ion beam-emitting optical system 14 may be positioned in the oblique direction inclined by a predetermined angle with respect to the vertical direction.

The gaseous ion beam-emitting optical system 18 emits a gaseous ion beam (GB), such as an argon ion beam. The gaseous ion beam-emitting optical system 18 can ionize argon gas and emits a beam of the generated argon ions at a low acceleration voltage of about 1 kV. Such gaseous ion beams (GBs) are less focused than focused ion beams (FIBs), resulting in lower etching rates on the sample piece S or micro sample piece Q. Therefore, GBs are suitable for precision finishing processing of the sample piece S or micro sample piece Q.

The detector 16 detects the intensity (i.e., amount) of secondary charged particles R (i.e., secondary electrons or secondary ions) emitted from the irradiation target when the irradiation targets such as the sample V, sample piece S, and needle 19a are irradiated with the charged particle beam or the electron beam and outputs information on the detected amount of the secondary charged particles R. The detector 16 is disposed inside the sample chamber 11 at a position where the amount of secondary charged particles R can be detected, for example, at a position obliquely above the irradiation target such as the sample V or Sample S in the irradiation region. The detector 16 is fixed to the sample chamber 11.

The gas supply unit 17 is fixed to the sample chamber 11 and has a gas ejection unit (also referred to as a nozzle) inside the sample chamber 11, and is arranged to face the stage 12. The gas supply unit 17 can supply an etching gas to selectively promote etching of the sample V or sample piece S depending on the material of the sample V or sample piece S when the sample V or sample piece S is etched by the charged particle beam and can supply a deposition gas to form a metal or insulator deposition film on the surface of the sample V or sample piece S.

The needle drive mechanism 19b, which is a part of the sample piece transfer means 19, is disposed inside the sample chamber 11 in a state of being connected with the needle 19a, and displaces the needle 19a according to a control signal output from the computer 22. The needle drive mechanism 19b is integrated with the stage 12. For example, when the stage 12 is rotated around the tilt axis (i.e., X or Y axis) by the tilt mechanism 13b, the needle drive mechanism 19b and the stage 12 move together.

The needle drive mechanism 19b has a moving mechanism (not illustrated) that moves the needle 19a in parallel along each of the three-dimensional coordinate axes and a rotation mechanism (not illustrated) that rotates the needle 19a around the central axis of the needle 19a.

The three-dimensional coordinate axes are independent of the triaxial rectangular coordinate system of the sample stage. The three-dimensional coordinate axes are a triaxial rectangular coordinate system with two-dimensional coordinate axes parallel to the surface of the stage 12. When the surface of the stage 12 is in a tilted or rotated state, this coordinate system will be tilted and rotated.

The computer 22 controls at least the stage drive mechanism 13, the focused ion beam-emitting optical system 14, the electron beam-emitting optical system 15, the gas supply unit 17, and the needle drive mechanism 19b.

The computer 22 is disposed outside the sample chamber 11. The computer 22 is connected to a display device 21 and input devices 23 such as a mouse and keyboard that output signals in response to input operations made by the operator. The computer 22 controls the overall operation of the charged particle beam device 10 according to signals output from the input devices 23 or signals generated by a predetermined automatic operation control process.

The computer 22 derives the beam diameter of the charged particle beam emitted by the focused ion beam-emitting optical system 14. An example of a beam diameter is expressed as in Equation 1.

$${D = [ {( 2 M \times Rs )}^{2} + {\{ ( 1 / 2 ) \times Csi \times {ai}^{3} \}}^{2} + {( Cci \times ai \times Δ V / V )}^{2} )}^{0.5 \cdot } \qquad ( 1 )$$

In Equation (1), D is the beam diameter, M is the optical system magnification, Rs is the source radius, Csi is the spherical aberration coefficient, ai is the image plane opening half angle, Cci is the chromatic aberration coefficient, AV is the energy spread, and V is the acceleration energy.

The computer 22 sets multiple irradiation locations for the charged particle beam D on the basis of the derived beam diameter D of the charged particle beam. An example of the multiple irradiation locations for the charged particle beam is the spacing between adjacent irradiation locations for the charged particle beam.

The computer 22 derives a processing depth for the charged particle beam to be emitted by the focused ion beam-emitting optical system 14 at each of multiple irradiation locations. An example of the processing depth is expressed as in Equation 2.

$$Processing depth = desired processing depth \times Tan 30 ° or more and Tan 89.8 ° or less of beam radius \qquad ( 2 )$$

The computer 22 sets a beam irradiation amount on the basis of each of the derived processing depths at the respective irradiation locations.

Based on the information specifying the multiple irradiation locations of the charged particle beam and the information specifying a beam irradiation amount for each of the multiple irradiation locations, the computer 22 creates control signals to cause the focused ion beam-emitting optical system 14 and the stage drive mechanism 13 to emit the charged particle beam to each of the multiple irradiation locations.

The computer 22 outputs control signals to the focused ion beam-emitting optical system 14 and the stage drive mechanism 13. The focused ion beam-emitting optical system 14 acquires the control signal output from the computer 22 and controls inputs to a lens electrode and a scan electrode of the focused ion beam-emitting optical system 14 according to the acquired control signal, thereby controlling the irradiation location, beam diameter, and beam amount of the charged particle beam emitted by the focused ion beam-emitting optical system 14. The stage drive mechanism 13 acquires a control signal output from the computer 22, and controls the irradiation location of the charged particle beam emitted by the focused ion beam-emitting optical system 14 according to the acquired control signals by displacing the stage 12 with respect to a predetermined axis.

The computer 22 converts the detected amount of secondary charged particles R detected by the detector 16 while scanning the irradiation location of the charged particle beam into a brightness signal on the irradiation location, and generates image data showing the shape of the irradiation target on the basis of the two-dimensional positional distribution of the detected amount of secondary charged particles R. In an absorption current imaging mode, the computer 22 detects the absorption current flowing to the needle 19a while scanning the irradiation location of the charged particle beam, thereby generating absorption current image data that indicates the shape of the needle 19a in the form of the two-dimensional positional distribution of the absorbed current (absorption current image).

The computer 22 displays a screen on the display unit 21 for allowing operations such as zooming in, zooming out, moving, and rotating each image data, as well as each piece of the generated image data. The computer 22 displays a screen on display unit 21 for allowing various setting operations such as mode selection and processing settings in an automatic sequence control process.

A sample processing method using the charged particle beam device 10 with the configuration described above will be described below.

FIG. 2 is a diagram illustrating Example 1 of a location irradiated with a charged particle beam device of the charged particle beam device according to the embodiment. “P01” to “P05” indicate the irradiation locations of the charged particle beam on the sample. “B01” to “B05” indicate the irradiation regions of the charged particle beam on the sample.

The focused ion beam-emitting optical system 14 creates a rectangular hole in the sample with the use of a charged particle beam, thereby rendering the cross section exposed. The rectangular hole is used as an electron beam path for observation under a scanning electron microscope (SEM). The computer 22 sets the exposed cross section as the processing region.

The computer 22 derives the beam diameter D of the charged particle beam and sets multiple irradiation locations for the charged particle beam D on the basis of the derived beam diameter D of the charged particle beam. An example of the multiple irradiation locations for the charged particle beam is the spacing between adjacent irradiation locations for the charged particle beam. Here, the case where information specifying a spacing between irradiation locations where the charged particle beams are adjacent to each other is applied as the multiple irradiation locations for the charged particle beam is described.

The computer 22 sets an irradiation location where the irradiation regions of the adjacent charged particle beams among the plurality of charged particle beam overlap, on the basis of the beam diameter D of the charged particle beam. Specifically, the computer sets a spacing between each of the plurality of charged particles beams emitted in the X-axis direction to be more than or equal to 50% and less than or equal to 90% of the beam diameter D of the charged particle beam and preferably be more than or equal to 70% and less than or equal to 90% of the beam diameter D. FIG. 2 illustrates a case in which among a plurality of charged particle beams emitted in the X-axis direction, the spacing between adjacent charged particle beams is set to be 50% of the charged particle beam diameter.

The computer 22 derives a processing depth for the charged particle beam to be emitted by the focused ion beam-emitting optical system 14 at each of the multiple irradiation locations. The computer 22 sets a beam irradiation amount on the basis of each of the derived processing depths at each of the irradiation locations.

The focused ion beam-emitting optical system 14 performs slicing processing by sequentially emitting a charged particle beam with the set beam irradiation amount to irradiation locations P01, P02, P03, P04, and P05 based on the scan direction shown in set processing region (1). After the slicing process is completed, the new cross section, which is called observation surface, produced by the slicing process is photographed with an SEM.

This process will be described in detail below. The focused ion beam-emitting optical system 14 performs slicing processing on the charged particle beam irradiation region B01 by emitting a charged particle beam to the irradiation location P01 by the set beam irradiation amount.

The focused ion beam-emitting optical system 14 performs slicing processing on the charged particle beam irradiation region B02 by emitting a charged particle beam to the irradiation location P02 by the set beam irradiation amount. There is an overlapping area in which the charged particle beam irradiation region B02 and the charged particle beam irradiation region B01 overlap. The focused ion beam-emitting optical system 14 can emit a charged particle beam to an irradiation location where the edge effect can be adequately obtained because the focused ion beam-emitting optical system 14 emits a charged particle beam to the irradiation location P02 where there is an overlapping area in which the charged particle beam irradiation region B02 and the previously irradiated region B01 overlap. This overlapping irradiation area is sliced by both the charged particle beam emitted to the irradiation location P01 and the charged particle beam emitted to the irradiation location P02. This allows the desired slicing depth to be maintained.

Next, the focused ion beam-emitting optical system 14 performs slicing processing on the charged particle beam irradiation region B03 by emitting a charged particle beam to the irradiation location P03 by the set beam irradiation amount. There is an overlapping area in which the charged particle beam irradiation region B03 and the charged particle beam irradiation region B02 overlap. The focused ion beam-emitting optical system 14 can emit a charged particle beam to an irradiation location where the edge effect can be adequately obtained because the focused ion beam-emitting optical system 14 emits a charged particle beam to the irradiation location P03 in which there is an overlapping area in which the charged particle beam irradiation region B03 and the previously irradiated region B02 overlap. This overlapping irradiation area is sliced by both the charged particle beam emitted to the irradiation location P02 and the charged particle beam emitted to the irradiation location P03. This allows the desired slicing depth to be maintained.

The focused ion beam-emitting optical system 14 performs slicing processing on the charged particle beam irradiation region B04 by emitting a charged particle beam to the irradiation location P04 by the set beam irradiation amount. There is an overlapping area in which the charged particle beam irradiation region B04 and the charged particle beam irradiation region B03 overlap. The focused ion beam-emitting optical system 14 can emit a charged particle beam to an irradiation location where the edge effect can be adequately obtained because the focused ion beam-emitting optical system 14 emits a charged particle beam to the irradiation location P04 where there is an overlapping area in which the charged particle beam irradiation region B04 and the previously irradiated region B03 overlap. This overlapping irradiation area is sliced by both the charged particle beam emitted to the irradiation location P03 and the charged particle beam emitted to the irradiation location P04. This allows the desired slicing depth to be maintained.

Next, the focused ion beam-emitting optical system 14 performs slicing processing on the charged particle beam irradiation region B05 by emitting a charged particle beam to the irradiation location P05 by the set beam irradiation amount. There is an overlapping area in which the charged particle beam irradiation region B05 and the charged particle beam irradiation region B04 overlap. The focused ion beam-emitting optical system 14 can emit a charged particle beam to an irradiation location where the edge effect can be adequately obtained because the focused ion beam-emitting optical system 14 emits a charged particle beam to the irradiation location P04 where there is an overlapping area in which the charged particle beam irradiation region B04 and the previously irradiated region B03 overlap one another. This overlapping irradiation area is sliced by both the charged particle beam emitted to the irradiation location P04 and the charged particle beam emitted to the irradiation location P05. This allows the desired slicing depth to be maintained.

In the example shown in FIG. 2, a case has been described in which five charged particle beam irradiation locations are set for the focused ion beam-emitting optical system 14, but the present invention is not limited to this example. For example, two to four irradiation locations may be set for the focused ion beam-emitting optical system 14, or six or more irradiation locations may be set.

Since the focused ion beam-emitting optical system 14 emits a charged particle beam to an irradiation location where there is an overlapping area in which the charged particle beam irradiation region and the previously irradiated region overlap one another, the charged particle beam always can be emitted to the irradiation location where the edge effect can be adequately obtained. This allows the desired slicing depth to be maintained.

Next, the processing procedure of the charged particle beam device 10 will be described.

FIG. 3 is a flowchart illustrating Example 1 of processing procedures of the charged particle beam device according to the embodiment. Referring to FIG. 3, an operation to be performed after the computer 22 sets an exposed cross section as the processing region in a state in which the focused ion beam-emitting optical system 14 irradiates the sample with a charged particle beam to create a rectangular hole, thereby exposing the cross section, will be described.

### (Step S1-1)

In the charged particle beam device 10, the computer 22 derives the beam diameter D of a charged particle beam to be emitted from the focused ion beam-emitting optical system 14.

### (Step S2-1)

In the charged particle beam device 10, the computer 22 derives multiple location s to be irradiated with a focused ion beam in X-axis direction on the basis of the derived beam diameter D of the charged particle beam, and sets the derived multiple irradiation locations.

### (Step S3-1)

In the charged particle beam device 10, the computer 22 derives a processing depth at each of the multiple irradiation locations for the charged particle beam to be emitted by the focused ion beam-emitting optical system 14. The computer 22 sets a beam irradiation amount on the basis of each of the derived processing depths at each of the irradiation locations of the charged particle beam.

### (Step S4-1)

In the charged particle beam device 10, based on the information specifying the multiple irradiation locations of the charged particle beam and the information specifying a beam irradiation amount for each of the multiple irradiation locations, the computer 22 creates control signals to cause the focused ion beam-emitting optical system 14 and the stage drive mechanism 13 to emit the charged particle beam to each of the multiple irradiation locations.

### (Step S5-1)

In the charged particle beam device 10, the computer 22 outputs control signals to the focused ion beam-emitting optical system 14 and the stage drive mechanism 13. The focused ion beam-emitting optical system 14 and the stage drive mechanism 13 acquire the control signals from the computer 22 and perform slicing processing according to the acquired control signals.

In the aforementioned embodiment, the case in which the charged particle beam device 10 derives multiple irradiation locations of the charged particle beam on the basis of the beam diameter D of the charged particle beam to be emitted by the focused ion beam-emitting optical system 14 is described, but the invention is not limited to the described embodiment. For example, the computer 22 may derive multiple irradiation locations of the charged particle beam D on the basis of an acceleration voltage. The profile of the charged particle beam changes according to the acceleration voltage. The computer 22 may derive spacing between the irradiation locations based on the profile (shape) of the charged particle beam.

In the aforementioned embodiment, the case in which the charged particle beam device 10 sets multiple irradiation locations in a single direction, such as X-axis direction of the sample is described, but the invention is not limited thereto. For example, the charged particle beam device 10 may set multiple irradiation locations for the charged particle beam in two directions, such as X-axis direction and Y-axis direction of the sample. As an example, the case in which the charged particle beam device 10 sets multiple irradiation locations for the charged particle beam in two directions, such as X-axis direction and Y-axis direction, will be described.

FIG. 4 is a diagram illustrating Example 2 of a location irradiated with a charged particle beam of the charged particle beam device according to the embodiment. “P11” to “45” indicate the irradiation locations of the charged particle beam on the sample. “B11” to “B45” indicate the irradiation regions of the charged particle beam on the sample.

The focused ion beam-emitting optical system 14 creates a rectangular hole in the sample with the use of a charged particle beam, thereby rendering a cross section exposed. The rectangular hole is used as an electron beam path for SEM observation. The computer 22 sets the exposed cross section as a processing region.

The computer 22 derives the beam diameter D of the charged particle beam and sets multiple irradiation locations for the charged particle beam on the basis of the derived beam diameter D of the charged particle beam. An example of the multiple irradiation locations for the charged particle beam is the spacing between irradiation locations where the charged particle beams are adjacent to each other. Here, the case where information specifying a spacing between irradiation locations where the charged particle beams are adjacent to each other is applied as the multiple irradiation locations for the charged particle beam will be described

The computer 22 sets an irradiation location where the irradiation regions of the adjacent charged particle beams among the plurality of charged particle beams overlap one another, on the basis of the beam diameter D of the charged particle beam. Specifically, the computer sets a spacing between each of the plurality of charged particles beams emitted in the X-axis direction and Y-axis direction to be more than or equal to 50% and less than or equal to 90% of the beam diameter D of the charged particle beam and preferably be more than or equal to 70% e and less than or equal to 90% or less of the beam diameter D. FIG. 4 illustrates a case in which among a plurality of charged particle beams emitted in the X-axis direction, the spacing between the adjacent charged particle beams is set to be 50% of the charged particle beam diameter, and among a plurality of charged particle beams emitted in the Y-axis direction, the spacing between the adjacent charged particle beams is set to be 50% of the charged particle beam diameter.

Here, although the case where the spacing between the adjacent charged particle beams among the plurality of charged particle beams emitted in the X-axis direction is set to be 50% of the charged particle beam diameter, and the spacing between the adjacent charged particle beams among the plurality of charged particle beams emitted in the Y-axis direction is set to be 50% of the charged particle beam diameter is described, the invention is not limited thereto. For example, the spacing between the adjacent charged particle beams among the plurality of charged particle beams emitted in the X-axis direction may be set to be different from the spacing between the adjacent charged particle beams among the plurality of charged particle beams emitted in the Y-axis direction.

The computer 22 derives a processing depth for the charged particle beam to be emitted by the focused ion beam-emitting optical system 14 at each of the multiple irradiation locations. An example of the processing depth is expressed as in Equation 2. The computer 22 sets a beam irradiation amount on the basis of each of the derived processing depths at each of the irradiation locations.

The focused ion beam-emitting optical system 14 performs slicing processing by sequentially emitting a charged particle beam with the set beam irradiation amount to irradiation locations P11, P12, P13, P14, and P15 on the basis of the scan direction indicated by the first slicing (1) in the set processing region. After the first slicing processing (1) is completed, the new cross section, which is called observation surface, produced by the slicing processing is photographed with an SEM.

The focused ion beam-emitting optical system 14 performs slicing processing by sequentially emitting a charged particle beam with the set beam irradiation amount to irradiation locations P21, P22, P23, P24, and P25 on the basis of the scan direction indicated by the second slicing (2) in the set processing region. After the second slicing processing (2) is completed, the new cross section, which is called observation surface, produced by the slicing processing is photographed with an SEM.

The focused ion beam-emitting optical system 14 performs slicing processing by sequentially emitting a charged particle beam with the set beam irradiation amount to irradiation locations P31, P32, P33, P34, and P35 on the basis of the scan direction indicated by the third slicing (3) in the set processing region. After the first slicing processing (3) is completed, the new cross section, which is called observation surface, produced by the slicing processing is photographed with an SEM.

The focused ion beam-emitting optical system 14 performs slicing processing by sequentially emitting a charged particle beam with the set beam irradiation amount to irradiation locations P41, P42, P43, P44, and P45 on the basis of the scan direction indicated by the fourth slicing (4) in the set processing region. After the first slicing processing (4) is completed, the new cross section, which is called observation surface, produced by the slicing processing is photographed with an SEM.

This process will be described in detail below. The first slicing (1) will be described. The focused ion beam-emitting optical system 14 performs slicing processing on the charged particle beam irradiation region B11 by emitting a charged particle beam to the irradiation location P11 by the set beam irradiation amount.

The focused ion beam-emitting optical system 14 performs slicing processing on the charged particle beam irradiation region B12 by emitting a charged particle beam to the irradiation location P12 by the set beam irradiation amount. There is an overlapping area in which the charged particle beam irradiation region B12 and the charged particle beam irradiation region B11 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P12 where there is an overlapping area in which the charged particle beam irradiation region B12 and the previously irradiated region B11 overlap one another. This overlapping irradiation area is sliced by both the charged particle beam emitted to the irradiation location P11 and the charged particle beam emitted to the irradiation location P12. This allows the desired slicing depth to be maintained.

Next, the focused ion beam-emitting optical system 14 performs slicing processing on the charged particle beam irradiation region B13 by emitting a charged particle beam to the irradiation location P13 by the set beam irradiation amount. There is an overlapping area in which the charged particle beam irradiation region B13 and the charged particle beam irradiation region B12 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P13 where there is an overlapping area in which the charged particle beam irradiation region B13 and the previously irradiated region B12 overlap one another. This overlapping irradiation area is sliced by both the charged particle beam emitted to the irradiation location P12 and the charged particle beam emitted to the irradiation location P13. This allows the desired slicing depth to be maintained.

Next, the focused ion beam-emitting optical system 14 performs slicing processing on the charged particle beam irradiation region B14 by emitting a charged particle beam to the irradiation location P14 by the set beam irradiation amount. There is an overlapping area in which the charged particle beam irradiation region B14 and the charged particle beam irradiation region B13 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P14 where there is an overlapping area in which the charged particle beam irradiation region B14 and the previously irradiated region B13 overlap one another. This overlapping irradiation area is sliced by both the charged particle beam emitted to the irradiation location P13 and the charged particle beam emitted to the irradiation location P14. This allows the desired slicing depth to be maintained.

Next, the focused ion beam-emitting optical system 14 performs slicing processing on the charged particle beam irradiation region B15 by emitting a charged particle beam to the irradiation location P15 by the set beam irradiation amount. There is an overlapping area in which the charged particle beam irradiation region B15 and the charged particle beam irradiation region B14 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P14 where there is an overlapping area in which the charged particle beam irradiation region B14 and the previously irradiated region B13 overlap one another. This overlapping irradiation area is sliced by both the charged particle beam emitted to the irradiation location P14 and the charged particle beam emitted to the irradiation location P15. This allows the desired slicing depth to be maintained.

The second slicing (2) will be described. The focused ion beam-emitting optical system 14 performs slicing processing on the charged particle beam irradiation region B21 by emitting a charged particle beam to the irradiation location P21 by the set beam irradiation amount. There is an overlapping area in which the charged particle beam irradiation region B21, the charged particle beam irradiation region B11 and the charged particle beam irradiation region B12 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P21 where there is an overlapping area in which the charged particle beam irradiation region B21 and the previously irradiated region B11 and B12 overlap one another. This overlapping irradiation area is sliced by the charged particle beam emitted to the irradiation location P21, the charged particle emitted to the irradiation location P11 and the charged particle beam emitted to the irradiation location P12. This allows the desired slicing depth to be maintained.

Next, the focused ion beam-emitting optical system 14 performs slicing processing on the charged particle beam irradiation region B22 by emitting a charged particle beam to the irradiation location P22 by the set beam irradiation amount. There is an overlapping area in which the charged particle beam irradiation region B22, the charged particle beam irradiation region B11, the charged particle beam irradiation region B12, the charged particle beam irradiation region B13, and the charged particle beam irradiation region B21 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P22 having an overlapping area in which the charged particle beam irradiation region B22 overlaps the previously irradiated region B11, the previously irradiated region B12, the previously irradiated region B13, and the previously irradiated region B21. This overlapping irradiation area is sliced by the charged particle beam emitted to the irradiation location P22, the charged particle beam emitted to the irradiation location P11, the charged particle beam emitted to the irradiation location P12, the charged particle beam emitted to the irradiation location P13, and the charged particle beam emitted to the irradiation location P21. This allows the desired slicing depth to be maintained.

Next, the focused ion beam-emitting optical system 14 performs slicing processing on the charged particle beam irradiation region B23 by emitting a charged particle beam to the irradiation location P23 by the set beam irradiation amount. There is an overlapping area in which the charged particle beam irradiation region B23, the charged particle beam irradiation region B12, the charged particle beam irradiation region B13, the charged particle beam irradiation region B14, and the charged particle beam irradiation region B22 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P23 having an overlapping area in which the charged particle beam irradiation region B23 overlaps the previously irradiated region B12, the previously irradiated region B13, the previously irradiated region B14, and the previously irradiated region B22. This overlapping irradiation area is sliced by the charged particle beam emitted to the irradiation location P23, the charged particle beam emitted to the irradiation location P12, the charged particle beam emitted to the irradiation location P13, the charged particle beam emitted to the irradiation location P14, and the charged particle beam emitted to the irradiation location P22. This allows the desired slicing depth to be maintained.

Next, the focused ion beam-emitting optical system 14 performs slicing processing on the charged particle beam irradiation region B24 by emitting a charged particle beam to the irradiation location P24 by the set beam irradiation amount. There is an overlapping area in which the charged particle beam irradiation region B24, the charged particle beam irradiation region B13, the charged particle beam irradiation region B14, the charged particle beam irradiation region B15, and the charged particle beam irradiation region B23 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P24 having an overlapping area in which the charged particle beam irradiation region B24 overlaps the previously irradiated region B13, the previously irradiated region B14, the previously irradiated region B15, and the previously irradiated region B23. This overlapping irradiation area is sliced by the charged particle beam emitted to the irradiation location P24, the charged particle beam emitted to the irradiation location P13, the charged particle beam emitted to the irradiation location P14, the charged particle beam emitted to the irradiation location P15, and the charged particle beam emitted to the irradiation location P23. This allows the desired slicing depth to be maintained.

The focused ion beam-emitting optical system 14 performs slicing processing on the charged particle beam irradiation region B25 by emitting a charged particle beam to the irradiation location P25 by the set beam irradiation amount. There is an overlapping area in which the charged particle beam irradiation region the charged particle beam irradiation region B25, the charged particle beam irradiation region B14, the charged particle beam irradiation region B15, and the charged particle beam irradiation region B24 overlap one another. The focused ion beam-emitting optical system 14 can emit a charged particle beam to an irradiation location where the edge effect can be adequately obtained because the focused ion beam-emitting optical system 14 emits a charged particle beam to the irradiation location P25 having an overlapping area in which the charged particle beam irradiation region B25 overlaps the previously irradiated region B14, the previously irradiated region B15, and the previously irradiated region B24. This overlapping irradiation area is sliced by the charged particle beam emitted to the irradiation location P25, the charged particle beam emitted to the irradiation location P14, the charged particle beam emitted to the irradiation location P15, and the charged particle beam emitted to the irradiation location P24. This allows the desired slicing depth to be maintained.

The third slicing (3) and the fourth slicing (4) are similar to the second slicing (2), so a description thereabout will be omitted here.

Since the focused ion beam-emitting optical system 14 emits a charged particle beam to an irradiation location where there is an overlapping area in which the charged particle beam irradiation region and the previously irradiated region overlap, the charged particle beam always can be emitted to the irradiation location where the edge effect can be adequately obtained. This allows the desired slicing depth to be maintained.

Next, the processing procedure of the charged particle beam device 10 will be described.

FIG. 5 is a flowchart illustrating Example 2 of processing procedures of the charged particle beam device according to the embodiment. Referring to FIG. 5, an operation to be performed after the computer 22 sets an exposed cross section as the processing region in a state in which the focused ion beam-emitting optical system 14 irradiates the sample with an electron beam to create a rectangular hole, thereby exposing a cross section, will be described.

### (Step S1-2)

In the charged particle beam device 10, the computer 22 derives the beam diameter D of a charged particle beam to be emitted from the focused ion beam-emitting optical system 14.

### (Step S2-2)

In the charged particle beam device 10, the computer 22 derives multiple locations to be irradiated with a focused ion beam in X-axis direction and Y-axis direction on the basis of the derived beam diameter D of the charged particle beam, and sets the derived multiple irradiation locations.

### (Step S3-1)

In the charged particle beam device 10, the computer 22 derives a processing depth at each of the multiple irradiation locations for the charged particle beam to be emitted by the focused ion beam-emitting optical system 14. The computer 22 sets a beam irradiation amount on the basis of each of the derived processing depths at each of the irradiation locations of the charged particle beam.

### (Step S4-2)

In the charged particle beam device 10, based on the information specifying the multiple irradiation locations of the charged particle beam and the information specifying a beam irradiation amount for each of the multiple irradiation locations, the computer 22 creates control signals to cause the focused ion beam-emitting optical system 14 and the stage drive mechanism 13 to emit the charged particle beam to each of the multiple irradiation locations.

### (Step S5-2)

In the charged particle beam device 10, the computer 22 outputs control signals to the focused ion beam-emitting optical system 14 and the stage drive mechanism 13. The focused ion beam-emitting optical system 14 and the stage drive mechanism 13 acquire the control signals from the computer 22 and perform slicing processing in X-axis direction according to the acquired control signals.

### (Step S6-2)

In the charged particle beam device 10, the computer 22 determines whether the entire slicing process has been completed. When the entire slicing process is completed, the process ends.

### (Step S7-2)

In the charged particle beam device 10, when the computer 22 determines that the slicing processes have not yet been completed, the stage drive mechanism 13 shifts the processing location in Y-axis direction. Next, S4-2 is performed.

The charged particle beam device 10 according to the present embodiment is a charged particle beam device for processing a sample, the charged particle beam device including: a charged particle beam-emitting optical system the focused ion beam-emitting optical system 14 that emits a charged particle beam; a sample stage that holds a sample; a drive mechanism as the stage drive mechanism 13 that drives the sample stage; and a computer that sets a cross section of the sample in a processing region of the sample and controls the charged particle beam-emitting optical system and the drive mechanism when the set processing region is sliced. The computer 22 sets an irradiation location to a location where each of a plurality of charged particle beams emitted in a first direction, such as X-axis direction, of the sample processing region overlap when the sample is sliced in the processing region. Due to the configuration described above, the focused ion beam-emitting optical system 14 can emit a charged particle to an irradiation location where the edge effect can be adequately obtained because the focused ion beam-emitting optical system 14 emits a charged particle to the irradiation location where there is an overlapping area in which the charged particle beam irradiation region and the previously irradiated region overlap one another in the first direction. Since it is possible to emit a beam to the irradiation location at which the edge effect can be properly obtained, it is possible to considerably reduce the processing time by maximizing the edge effect.

In addition, the computer sets a spacing between each of the plurality of charged particle beams emitted in the first direction to be more than or equal to 50% and less than or equal to 90% of the diameter of the charged particle beam. Due to the configuration described above, the focused ion beam-emitting optical system 14 can emit a charged particle to an irradiation location where the edge effect can be adequately obtained because the focused ion beam-emitting optical system 14 emits a charged particle to the irradiation location where there is an overlapping area in which the charged particle beam irradiation region and the previously irradiated region overlap one another in the first direction. In the case of slicing at intervals of more than or equal to 50% and less than or equal to 90% of the beam diameter of the charged particle beam, the raster scan is performed such that the charged particle beam irradiation regions are overlapped by more than or equal to 50% and less than or equal to 90% during slicing processing for each spacing. When the charged particle beam irradiation region is controlled to be irradiated in the processing region, the charged particle beam is emitted such that the charged particle beam irradiation regions are overlapped by a predetermined amount.

The computer 22 sets an irradiation location to a location where one or more charged particle beams emitted in a second direction, such as Y-axis direction which is orthogonal to the first direction, such as X-axis direction, overlap when the processing region of the sample is sliced. Due to the configuration described above, the focused ion beam-emitting optical system 14 can emit a charged particle to an irradiation location where the edge effect can be adequately obtained because the focused ion beam-emitting optical system 14 emits a charged particle to the irradiation location where there is an overlapping area in which the charged particle beam irradiation region and the previously irradiated region overlap one another in the first direction and the second direction.

In addition, the computer sets a spacing between one or more charged particles beams emitted in the second direction to be more than or equal to 50% and less than or equal to 90% of the diameter of the charged particle beam. Due to the configuration described above, the focused ion beam-emitting optical system 14 can emit a charged particle to an irradiation location where the edge effect can be adequately obtained because the focused ion beam-emitting optical system 14 emits a charged particle to the irradiation location where there is an overlapping area in which the charged particle beam irradiation region and the previously irradiated region overlap one another in the second direction. In the case of slicing at intervals of more than or equal to 50% and less than or equal to 90% of the beam diameter of the charged particle beam, the raster scan is performed such that the charged particle beam irradiation regions are overlapped by more than or equal to 50% and less than or equal to 90% during slicing processing for each spacing. When the charged particle beam irradiation region is controlled to be irradiated in the processing region, the charged particle beam is emitted such that the charged particle beam irradiation regions are overlapped by a predetermined amount.

In addition, the computer 22 sets a processing depth for each of a plurality of charged particles beams emitted in the first direction to be a desired processing depth multiplied by a number that is more than or equal to Tan 30° and less than or equal to Tan 89.8° of a beam radius. Due to this configuration, the focused ion beam-emitting optical system 14 can increase the sputtering efficiency in the first direction.

A program to implement all or part of the control function of the computer 22 of the charged particle beam device may be recorded on a computer-readable recording medium, and the program recorded on the recording medium may be read and executed by a computer system. The term “computer system” here refers to a computer system built into a charged particle beam device D1 or a composite charged particle beam device D and provided with an operating system (OS) and hardware devices such as peripheral devices. Here, the term “computer-readable recording medium” refers to a portable medium such as flexible disk, optical magnetic disk, ROM, CD-ROM, and other storage device such as a hard disk built into the computer system. In addition, the term “computer-readable recording medium” may also include a medium that can dynamically hold the program for a short period of time, such as a communication line in the case where the program is transmitted over a network such as the Internet or a communication line such as a telephone line, and a medium that holds the program for a certain period of time, such as a volatile memory provided in a computer system serving as a server or a client. The program may be used to implement some of the aforementioned functions, and may also be used to implement the aforementioned functions in conjunction with a program recorded in the computer system.

In addition, in the embodiments described above, the computer 22 may be partially or fully implemented as an integrated circuit such as a large scale integrated (LSI) circuit. Each function of the computer 22 may be individually processorized, or it may be partially or fully integrated and processorized. The integrated circuit is not limited to LSI, but may be implemented as a dedicated circuit or general-purpose processor. When an integrated circuit technology has emerged as an alternative to LSI due to advances in semiconductor technology, an integrated circuit based on such technology may be used.

The embodiments of the invention have been described in detail with reference to the drawings, but the specific configuration of the invention is not limited to the embodiments and can include designs that do not depart from the gist of the invention.

### EXPLANATION OF REFERENCE SYMBOLS

10 . . . Charged particle beam device, 11 . . . Sample chamber, 12 . . . Stage (sample stage), 13 . . . Stage drive mechanism, 14 . . . Focused ion beam-emitting optical system, 15 . . . Electron beam-emitting optical system, 16 . . . Detector, 17 . . . Gas supply unit, 18 . . . Gaseous ion, beam-emitting optical system, 19a . . . Needle, 19b . . . Needle drive mechanism, 20 . . . Absorption current detector, 21 . . . Display device, 22 . . . Computer, 23 . . . Input device, 33 . . . Sample stand, 34 . . . Columnar portion, C . . . Inclined portion, P . . . Sample piece holder, Q . . . Micro sample piece, R . . . Secondary charged particle, S . . . Sample piece, V . . . Sample

1. A charged particle beam device for processing a sample, the charged particle beam device comprising:
a charged particle beam-emitting optical system that emits a charged particle beam;
a sample stage that holds a sample;
a drive mechanism that drives the sample stage; and
a computer that sets a cross section of the sample in a processing region of the sample and controls the charged particle beam-emitting optical system and the drive mechanism when the processing region is sliced,
wherein the computer sets an irradiation location to a location where a plurality of charged particle beams emitted in a first direction of the processing region overlap one another when the processing region of the sample is sliced.

2. The charged particle beam device according to claim 1, wherein the computer sets a spacing between each of the plurality of charged particle beams emitted in the first direction to be more than or equal to 50% and less than or equal to 90% of diameter of the charged particle beam.

3. The charged particle beam device according to claim 1, wherein the computer sets the irradiation location to at a location where a plurality of charged particle beams emitted in a second direction orthogonal to the first direction overlap one another when the processing region of the sample is sliced.

4. The charged particle beam device according to claim 3, wherein the computer sets a spacing between each of the plurality of charged particle beams emitted in the second direction to be more than or equal to 50% and less than or equal to 90% of diameter of the charged particle beam.

5. The charged particle beam device according to claim 1, wherein the computer sets a processing depth for each of the plurality of charged particle beams emitted in the first direction to be a desired processing depth multiplied by a number that is more than or equal to Tan 30° and less than or equal to Tan 89.8° of a beam radius.

6. A method for controlling a charged particle beam device comprising a charged particle beam-emitting optical system that emits a charged particle beam, a sample stage that holds a sample, a drive mechanism that drives the sample stage, and a computer that sets a cross section of the sample in a processing region of the sample and controls the charged particle beam-emitting optical system and the drive mechanism when the processing region that is set is sliced, the method comprising:
setting an irradiation location with the computer at a location where a plurality of charged particle beams emitted in a first direction of the processing region overlap one another when the processing region of the sample is sliced; and
controlling the charged particle beam-emitting optical system and the drive mechanism with the computer so as to slice the sample by irradiating the irradiation location that is set with the charged particle beam.

7. The charged particle beam device according to claim 2, wherein the computer sets the irradiation location to at a location where a plurality of charged particle beams emitted in a second direction orthogonal to the first direction overlap one another when the processing region of the sample is sliced.

8. The charged particle beam device according to claim 7, wherein the computer sets a spacing between each of the plurality of charged particle beams emitted in the second direction to be more than or equal to 50% and less than or equal to 90% of diameter of the charged particle beam.
